(19) United States
(12) Patent Application Publication
(10) Pub. No.: US 2016/0334623 A1
(43) Pub. Date: Nov. 17, 2016

(54) DISPLAY DEVICE, DISPLAY METHOD, AND NON-TRANSITORY COMPUTER READABLE MEDIUM STORING DISPLAY PROGRAM

(71) Applicant: JVC KENWOOD Corporation, Yokohama-shi (JP)

(72) Inventor: Kazuhiro KISHI, Yokohama-shi (JP)

(21) Appl. No.: 15/221,484

(22) Filed: Jul. 27, 2016

Related U.S. Application Data
(63) Continuation of application No. PCT/JP2014/005127, filed on Oct. 8, 2014.

(30) Foreign Application Priority Data
Jan. 28, 2014 (JP) 2014-013099

(51) Int. Cl. G02B 27/01; H04R 29/00; G06F 3/16; H03G 3/04; B60K 35/00; G09G 5/00

(52) U.S. Cl. CPC G02B 27/017; B60K 35/00; G09G 5/005; G06F 3/165; H03G 3/04; H04R 29/008; G02B 2027/014; G02B 2027/0141; G09G 2320/0613; G09G 2380/10; B60K 2350/106; H04R 2499/13

(57) ABSTRACT

A display device includes a volume information obtaining unit configured to obtain volume change information for a sound output, a notification information obtaining unit configured to obtain notification information for a user, and a display unit configured to provide the user with a notification display according to the notification information obtained by the notification information obtaining unit and change a display mode so that the notification display will be distinct according to the volume change information obtained by the volume information obtaining unit.

### CROSS REFERENCE TO RELATED APPLICATION

The present application claims priority rights of and is based on PCT Application No. PCT/JP2014/005127, filed Oct. 8, 2014, which claims priority from Japanese Patent Application No. 2014-013099, filed on Jan. 28, 2014, the entire contents of which are hereby incorporated by reference.

### BACKGROUND

The present invention relates to a display device, a display method, and a non-transitory computer readable medium storing a display program that displays various information items and presents the information items to a user.

Head Up Displays (hereinafter referred to as HUDs) that display information to drivers of automobiles and the like through windshields to present the information to the drivers have been put into practical use. Head Mount Displays (hereinafter referred to as HMDs) that are worn on heads to enable transparent visual recognition of the outside have also been put into practical use, and it is expected that use of HMDs while users are on the move, for example, while users are walking, will increase.

### SUMMARY

Japanese Unexamined Patent Application Publication No. 2013-203103 and Japanese Unexamined Patent Application Publication No. 2010-211623 discloses a HUD and an HMD that display a notification such as an alert according to a desired purpose.

Such HUD and HMD may be used for display applications such as a media playback device with a sound output depending on a purpose of use or may be used in combination with a media playback device. For example, HUDs used by automobiles are used together with navigation devices and in-car audio devices. Further, HMDs are integrated with media playback devices or connected to transportable media playback devices.

In these applications, when volume of a sound output of the media playback device is changed, a user's attention will be focused on the sound output, the volume of which has been changed, and thus the user may be distracted from a notification display even when the HUD or HMD displays a notification such as an alert.

In order to solve the above-mentioned problem, a display device according to the exemplary embodiment includes: a volume information obtaining unit configured to obtain volume change information for a sound output; a notification information obtaining unit configured to obtain notification information for a user; and a display unit configured to provide the user with a notification display according to the notification information obtained by the notification information obtaining unit and change a display mode so that the notification display will be easily spotted by the user for a period that attracts a user's attention to sound due to a change in volume of the sound when the volume change information obtained by the volume information obtaining unit indicates a volume change to predetermined volume or higher, a volume change to the predetermined volume or lower, a volume change by a volume increase of a predetermined amount or greater, or a volume change by a volume reduction of a predetermined amount or greater.

Further, a display method according to the exemplary embodiment includes: a volume information obtaining step for obtaining volume change information for a sound output; a notification information obtaining step for obtaining notification information for a user; and a display changing step for providing the user with a notification display according to the notification information obtained in the notification information obtaining step and changing a display mode so that the notification display will be easily spotted by the user for a period that attracts a user's attention to sound due to a change in volume of the sound when the volume change information obtained in the volume information obtaining step indicates a volume change to predetermined volume or higher, a volume change to the predetermined volume or lower, a volume change by a volume increase of a predetermined amount or greater, or a volume change by a volume reduction of a predetermined amount or greater.

Furthermore, a display program according to the exemplary embodiment causes a computer for controlling a display device to display information in a range of user's view to execute: a volume information obtaining step for obtaining volume change information for a sound output; a notification information obtaining step for obtaining notification information for a user; and a display changing step for providing the user with a notification display according to the notification information obtained in the notification information obtaining step and changing a display mode so that the notification display will be easily spotted by the user for a period that attracts a user's attention to sound due to a change in volume of the sound when the volume change information obtained in the volume information obtaining step indicates a volume change to predetermined volume or higher, a volume change to the predetermined volume or lower, a volume change by a volume increase of a predetermined amount or greater, or a volume change by a volume reduction of a predetermined amount or greater.

### BRIEF DESCRIPTION OF THE DRAWINGS

FIG. 1 is a configuration block diagram conceptually showing a display device according to the exemplary embodiment;

FIG. 2 is a drawing schematically showing inside an automobile on which a display device according to a first exemplary embodiment is mounted;

FIG. 3 is a configuration block diagram of a HUD device that constitutes the display device according to the first exemplary embodiment;

FIG. 4 is a configuration block diagram of a media playback device that constitutes the display device according to the first exemplary embodiment;

FIG. 5 is a flowchart showing an operation example of the display device according to the first exemplary embodiment;

FIG. 6 is a display screen example of the display device according to the first exemplary embodiment;

FIG. 7 is a drawing showing an example of volume change information and timings for notification display;

FIG. 8 is a configuration block diagram of a media playback device that constitutes a display device according to a second exemplary embodiment;

FIG. 9 is a configuration block diagram of the media playback device that constitutes the display device according to the second exemplary embodiment;

FIG. 10 is a flowchart showing an operation example of the display device according to the second exemplary embodiment;

FIG. 11 is a drawing schematically showing a display device according to a third exemplary embodiment;

FIG. 12 is a configuration block diagram of an HMD projection unit that constitutes the display device according to the third exemplary embodiment;

FIG. 13 is a configuration block diagram of a media playback device that constitutes the display device according to the third exemplary embodiment; and

FIG. 14 is a display screen example of the display device according to the third exemplary embodiment.

### DETAILED DESCRIPTION

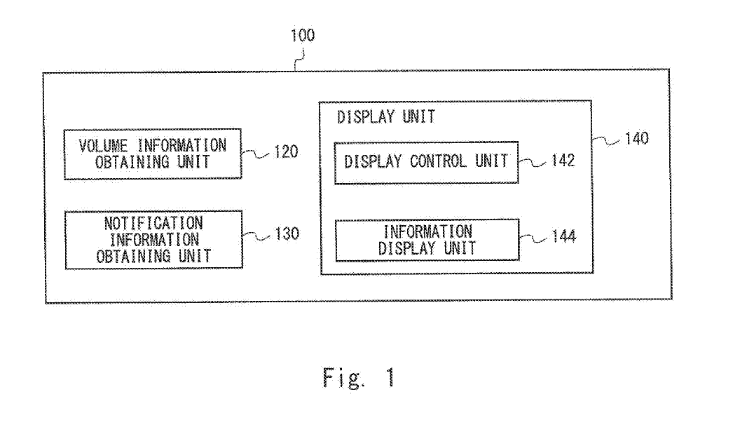

FIG. 1 is a configuration block diagram conceptually showing a display device 100 according to the exemplary embodiment and shows a configuration that is common to all exemplary embodiments described below. A display device 100 is configured to include a volume information obtaining unit 120, a notification information obtaining unit 130, and a display unit 140. The display unit 140 is configured to include an information display unit 144 that presents video to a user and a display control unit 142 that controls the video displayed on the information display unit 144. Specific examples of the components of the display device 100 will be described in the exemplary embodiments.

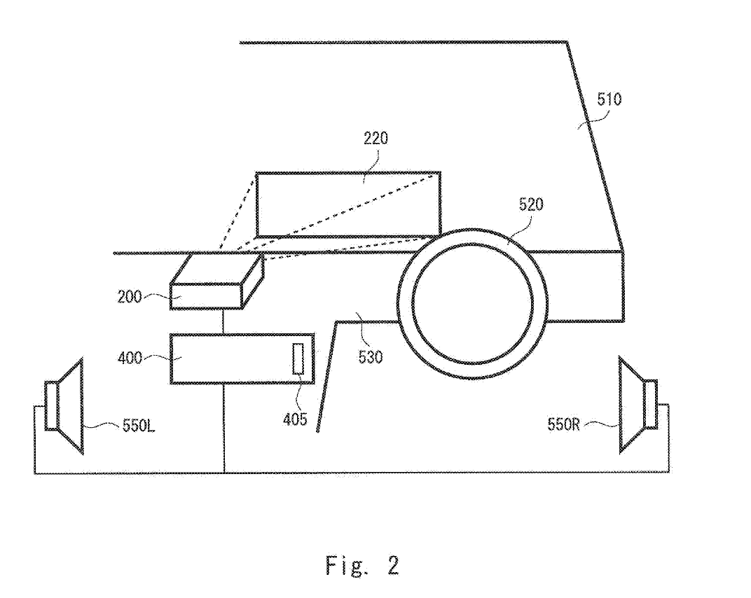

A first exemplary embodiment of the display device 100 will be described with reference to FIGS. 2 to 6. The display device 100 according to the first exemplary embodiment is configured using, as shown in FIG. 2, a HUD device 200 that projects and displays various information items inside an automobile as virtual images and a media playback device 400. The media playback device 400 according to the first exemplary embodiment is intended for use in various devices such as an in-car navigation device, an in-car audio device, or various mobile terminals such as a transportable navigation device and a transportable audio device. The display unit 140 is not limited to the HUD device 200 and may be a display unit included in a navigation device or the like.

As shown in FIG. 2, the HUD device 200 is mounted on a dashboard 530 or the like of the automobile and projects various information items at a position that enables primarily a driver of the automobile to visually recognize them as a virtual image 220. The virtual image 220 is projected on a windshield 510 or a combiner of the automobile. The HUD device 200 may be mounted on the dashboard 530 or may be mounted inside the dashboard 530. Alternatively, the HUD device 200 may be mounted on a ceiling, a rear view mirror, or the like of the automobile.

The media playback device 400 is mounted on, for example, the dashboard 530 or the like of the automobile and includes an operation input unit 405 that adjusts playback volume when contents including sound are played. The operation input unit 405 is an interface that allows the user to arbitrarily operate the playback volume and is achieved by various switches, a touch panel, a sound operation, and the like. The operation input unit 405 may be included in a steering wheel 520 of the automobile. The playback volume of sound signals from the media playback device 400 is adjusted by an operation on the operation input unit 405, and the sound signals are output from a speaker 550. In FIG. 2, although an example in which a left speaker 550L and a right speaker 550R constitute the speaker 550 is shown, a configuration of the speaker 550 is arbitrary.

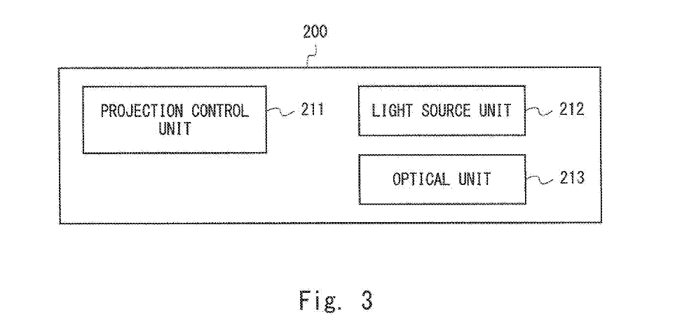

As shown in FIG. 3, the HUD device 200 is configured to include a projection control unit 211, a light source unit 212, and an optical unit 213. The projection control unit 211 includes a CPU (Central Processing Unit) and the like and controls inputs to and outputs from the HUD device 200 and operations of components of the HUD device 200. To be more specific, the projection control unit 211 controls an amount of light, a color tone, a display mode, and the like of the light source unit 212 according to video data to be projected that is input to the HUD device 200. Moreover, when the optical unit 213 has a configuration that generates projecting video by scanning light using a MEMS (Micro Electro Mechanical Systems) mirror, the projection control unit 211 controls wobbles of the MEMS mirror.

The light source unit 212 optically forms video projected by the HUD device 200. As a specific example, when the light source unit 212 uses an MEMS mirror, a laser diode as a light source and the MEMS mirror that scans light from the laser diode are included in the light source unit 212. When the light source unit 212 uses a liquid crystal display device, an LED (Light Emitting Diode) as a light source, a reflective or transmissive liquid crystal panel, a polarizing plate, and the like are included in the light source unit 212.

The optical unit 213 includes an optical element that projects the video to be projected that has been generated by the light source unit 212 as the virtual image 220 and includes various lenses such as a projection lens and the like, an intermediate image filter, a reflecting mirror, and the like.

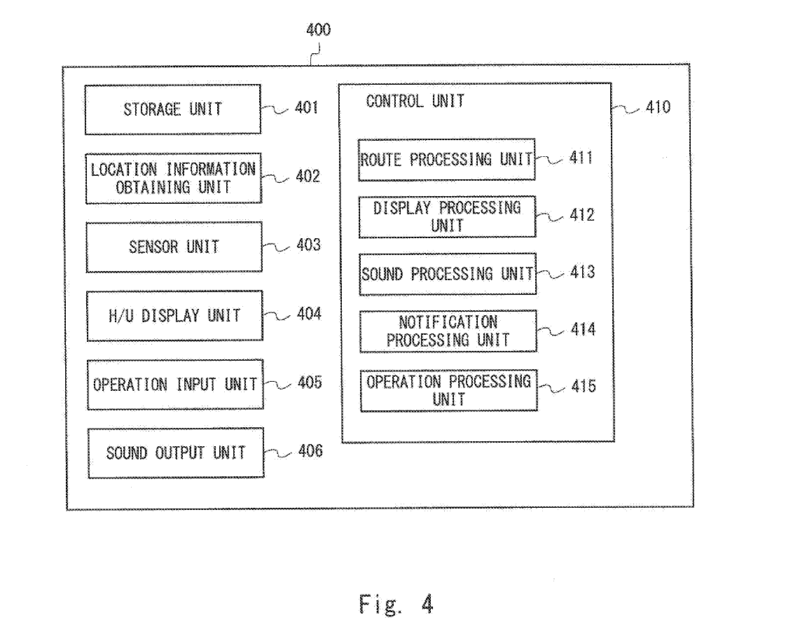

An example of a navigation device used in an automobile will be described as an example of the media playback device 400. As shown in FIG. 4, the media playback device 400 is configured to include a storage unit 401, a location information obtaining unit 402, a sensor unit 403, an H/U display unit 404, an operation input unit 405, a sound output unit 406, and a control unit 410.

The storage unit 401 stores sound contents, video contents, and various information items used for route guidance such as map information, display information, and the like. The control unit 410 controls reading various information items from and writing various information items to the storage unit 401. The storage unit 401 may be various storage media included in the media playback device 400, an external storage medium or an external storage device that can be used through various connections or communication.

The location information obtaining unit 402 is a GPS (Global Positioning System) receiver that obtains location information for the media playback device 400 as a navigation device to use it for the purpose of route guidance or to know locations of peripheral facilities of the automobile. The control unit 410, which will be described later, calculates a current location as latitude/longitude information according to GPS data from the location information obtaining unit 402 and uses it in route processing and the like.

The sensor unit 403 includes various sensors such as an acceleration sensor, a tilt sensor, and the like for improving accuracy of the current location information obtained from the location information obtaining unit 402. Values output from the sensor unit 403 are obtained by the control unit 410 and used for various processes. The sensor unit 403 includes sensors that obtain information on the surroundings of a vehicle including the media playback device 400 as the navigation device. Specific examples of such sensors are: a camera that images surroundings of the vehicle; and a millimeter wave sensor, an infrared sensor, or the like that detects an obstacle and the like around the vehicle.

The H/U (Head Unit) display unit 404 is a display device such as a liquid crystal display device included in the navigation device that is used as a head unit and displays a playback screen and the like for information related to the route guidance, neighboring facilities information, various setting screens, sound contents, and video contents according to control by the display processing unit 412, which will be described later.

The operation input unit 405 is a user interface for the user to operate the media playback device 400 and allows the user to perform input using various switches, a touch panel included in the H/U display unit 404, and sound. In regard to the operation signals input from the operation input unit 405, the operation processing unit 415 associates an input operation with processing and executes the processing. The operation input unit 405 accepts operations of the playback volume for the sound contents and video contents.

The sound output unit 406 outputs sound of various contents played by the media playback device 400. The sound output unit 406 outputs sound signals, on which processing such as decoding has been performed by the sound processing unit 413, which will be described later, to the speaker 550 shown in FIG. 2 when playback processing of various contents stored in the storage unit 401 and the like is performed. The sound output unit 406 may include an amplification function for a sound signal output and a D/A (Digital to Analog) conversion function. Examples of the contents played by the media playback device 400 are: sound contents and video contents stored in the storage unit 401, a disk drive, or the like (not shown); sound of radio broadcasting, and video and sound of television broadcasting that are received by a broadcasting reception unit (not shown); and various contents received by a communication unit (not shown) via a network.

The control unit 410 includes a CPU and a DSP (Digital Signal Processor), and a RAM, ROM, or the like that are used for operating the CPU and DSP. The ROM and the storage unit 401 of the control unit 410 store various programs for operating the media playback device 400. The control unit 410 achieves a route processing unit 411, the display processing unit 412, the sound processing unit 413, a notification processing unit 414, and the operation processing unit 415 as functions operated by these programs.

The route processing unit 411 executes processing to generate a route from a current location to a destination according to the map information stored in the storage unit 401, destination information specified using the operation input unit 405, the current location information based on signals received by the location information obtaining unit 402, and the like. The route generated by the route processing unit 411 is output to the H/U display unit 404 and HUD device 200 and then displayed. Further, the route processing unit 411 generates instruction information such as a travelling direction at a closest intersection and the like along the route, outputs the instruction information to the H/U display unit 404 and the HUD device 200. Then, the instruction information is displayed.

The display processing unit 412 controls display of the information output to the H/U display unit 404 and the HUD device 200. To be more specific, for example, the display processing unit 412 controls a configuration, display contents, display colors, display brightness, display timings, and the like of the information displayed on the H/U display unit 404 and the HUD device 200. Moreover, when the H/U display unit 404 operates as a touch panel, the display processing unit 412 displays various GUIs (Graphical User Interfaces) associated with touch operations.

The sound processing unit 413 processes sound to be output by the media playback device 400. Specific examples of such processing are: decode processing, sound quality change processing, volume change processing, and the like on sound data included in the various contents played by the media playback device 400.

The notification processing unit 414 performs processing to notify a user of information which the user should be notified of To be more specific, for example, the notification processing unit 414 analyzes an output of a camera included as the sensor unit 403 that images the surroundings of the vehicle or an output of the millimeter wave sensor, an infrared sensor, or the like included as the sensor unit 403 that detects an obstacle and the like around the vehicle. When a distance to another vehicle present in an area around the vehicle or a distance to a pedestrian, another automobile, a bicycle, or another object becomes less than a predetermined distance, the notification processing unit 414 issues a notification display instruction to the display processing unit 412 so that the H/U display unit 404 or the HUD device 200 displays a notification. Another example is that the notification processing unit 414 analyzes the output of the camera included as the sensor unit 403 that images the surroundings of the vehicle, and when a distance between a travelling vehicle and a center line extracted by image processing is rapidly reduced, or when the vehicle crosses the center line while travelling, the notification processing unit 414 issues a notification display instruction to the display processing unit 412 so that the H/U display unit 404 or the HUD device 200 displays a notification.

The notification processing unit 414 may obtain information which the user should be notified of from a roadside device for ITS (Intelligent Transport System) using the communication unit (not shown).

The notification processing unit 414 may perform the above notification instruction by a sound that is output from the speaker 550. Alternatively, notification by the sound may be combined with the notification display. In such cases, the notification processing unit 414 issues a notification sound output instruction to the sound processing unit 413 so that the notification is performed by the sound.

The operation processing unit 415 performs processing to accept operations on the operation input unit 405. When the operation input unit 405 is a switch or a touch panel, the operation processing unit 415 receives signals based on a result of an operation and passes the signals to corresponding operation processing. When the operation input unit 405 accepts sound inputs, the operation input unit 405 converts sound signals from a microphone included in the operation input unit 405 from digital to analog, performs processing such as a phonemic analysis, and then passes the processed signals to corresponding operation processing according to a result of the processing. More specifically, for example, when an operation of changing the playback volume is performed on the operation input unit 405 while the media playback device 400 plays the sound contents or the video contents including sound, the sound processing unit 413 changes the playback volume in response to the operation based on an evaluation by the operation processing unit 415 that volume operation processing is performed and based on an amount of the operation.

In the display device 100 in the first exemplary embodiment, the operation input unit 405 and the operation processing unit 415 function as the volume information obtaining unit 120. The sensor unit 403 and the notification processing unit 414 function as the notification information obtaining unit 130. The display processing unit 412 corresponds to the display control unit 142 that constitutes the display unit 140, and the H/U display unit 404 and the HUD device 200 correspond to the information display unit 144.

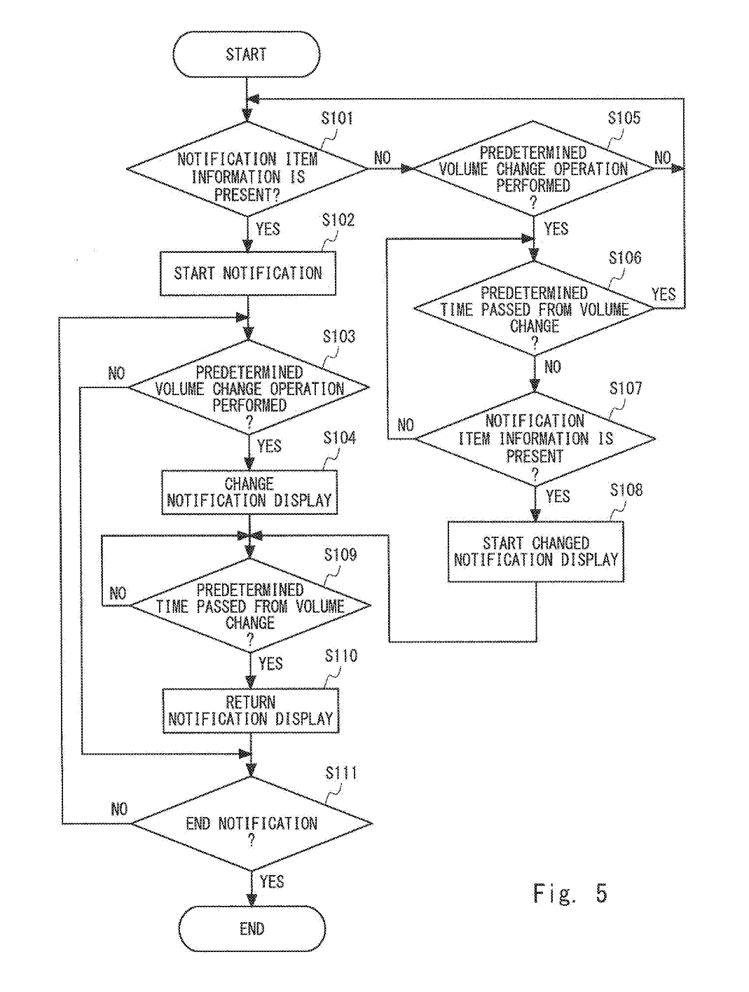

Next, an operation example of the display device 100 according to the first exemplary embodiment will be described. In the operation example shown in FIG. 5, it is assumed that the vehicle including the display device 100 is operating, and the media playback device 400 that constitutes the display device 100 is playing the contents including sound information.

When the vehicle is operating, devices such as a camera, a sensor, and the like included in the sensor unit 403 that obtain outer-vehicle information sequentially operate, and the notification processing unit 414 sequentially detects a condition for notification items. While the contents including the sound information are played, the sound processing unit 413 sequentially accepts volume operations on the operation input unit 405.

In such a state, when the notification processing unit 414 evaluates that there is notification item information (step S101: Yes), the notification processing unit 414 starts notification processing (S102). The notification processing executed here is to notify a driver who is the user of dangerous surrounding conditions and conditions of the vehicle by video or sound. More specifically, for example, when respective separation distances from other vehicles in front of and behind the driver's vehicle are small enough to be evaluated as being dangerous, notification processing unit 414 displays a notification on the H/U display unit 404 or the HUD device 200 indicating that conditions are dangerous. Alternatively, when the travelling vehicle is rapidly coming closer to a center line or crosses the center line, the notification processing unit 414 displays a notification on the H/U display unit 404 or the HUD device 200 that conditions are dangerous and also notifies the user that conditions are dangerous by sound.

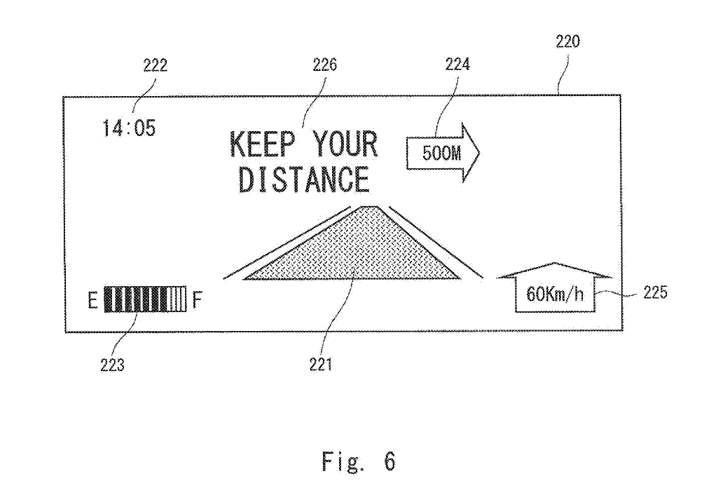

FIG. 6 shows an example of the notification executed in the step S102, and an example in which a notification is displayed on the virtual image 220 that is projected by the HUD device 200.

Display contents of the virtual image 220 are different from those of the H/U display unit 404 and are information necessary for primarily the user to frequently check while driving. Such information can be frequently checked because the virtual image 220 can be visually recognized by only a small movement of the eyes when the user is looking forward.

A travel path display part 221 shows a form of a road the vehicle is actually travelling on and presents a road width, a form of a curve, and the like to the user. The display of the travel path display part 221 uses the current location information obtained from the location information obtaining unit 402 and the map information stored in the storage unit 401. The time display part 222 displays a current time. A fuel display part 223 displays a remaining amount of fuel and amount of stored power. A planned travelling direction display part 224 displays a distance to and a travelling direction at an intersection at which the vehicle should make a turn according to the route generated by the route processing unit 411. A speed display part 225 displays a current traveling speed.

When the notification processing is executed in the step S102, the notification display part 226 is displayed on the virtual image 220. In a display example of FIG. 6, the notification display part 226 indicates that a separation distance from another car in front or behind the driver's vehicle is small, and thus the conditions are dangerous.

Referring again to FIG. 5, when the notification processing is started in the step S102, and while the notification processing is being executed, the sound processing unit 413 evaluates as to whether or not the operation input unit 405 has accepted a predetermined volume change operation (step S103). The predetermined volume change operation is an operation that increases the volume from volume less than a predetermined first threshold that has been previously set to volume greater than or equal to the first threshold. Another example of the predetermined volume change operation is a case when a first volume difference between volume before the volume change operation has been performed and volume after the volume change operation has been performed is a volume increase that is greater than or equal to a predetermined volume difference.

A volume change that causes the attention of the user to be focused on the sound and thus distracts the user from the notification display is not limited to an increase in the volume and instead also includes a reduction in the volume. The predetermined volume change operation in such a case is a case when an operation in which the volume is reduced from volume greater than or equal to a predetermined second threshold that has been previously set to become less than the second threshold is performed. Another example of the predetermined volume change operation is a case when a second volume difference between volume before the volume change operation and volume after the volume change operation has been performed thereon is a volume reduction that is greater than or equal to a predetermined volume difference.

As a condition of the volume change for increasing the volume and the volume change for reducing the volume, the volume set as the first threshold is greater than the volume set as the second threshold. Further, the first and second volume differences may be the same or different.

When it is evaluated that the predetermined volume change operation has been accepted in the step S103 (step S103: Yes), the display processing unit 412 changes the display of the notification display part 226 that has been displayed in the notification processing in the step S102 to make it distinct so that the display can be easily spotted by the user (step S104).

There are various display modes as specific examples of the change in the notification display part 226 executed in the step S104, such as increasing a display size of the notification display part 226, displaying the notification display part 226 in a distinct color tone, and blinking the notification display part 226.

When it is evaluated that the predetermined volume change operation has not been accepted in the step S103 (step S103: No), the notification processing unit 414 evaluates as to whether or not to end the notification processing (step S111). A specific example of a timing to end the notification that is evaluated in the step S111 is a timing when there is no longer a dangerous state which the user should be notified of.

When it is evaluated that the notification is ended in the step S111 (step S111: Yes), this processing is ended. When it is determined that the notification will not be ended (step S111: No), the process returns to the processing of the step S103.

The processing from the step S101 to the step S104 is performed when the volume change operation is accepted while executing the notification processing. Another execution timing is during the volume change operation or when the notification processing is started within a predetermined time from after the volume change operation. In such a case, when it is evaluated that there is no notification item information in the step S101 (step S101: No), the sound processing unit 413 evaluates as to whether or not the predetermined volume change operation has been accepted by the operation input unit 405 (step S105).

When it is evaluated that the predetermined volume change operation has been accepted in the step S105 (step S105: Yes), the sound processing unit 413 evaluates as to whether or not a predetermined time has passed from after the volume change operation in the step S105 (step S106). A specific example of the appropriate predetermined time here is about five to ten seconds, and the predetermined time preferably includes a time length that attracts user's attention to the sound, the volume of which has been changed.

When it is evaluated that the predetermined volume change operation has not been accepted in the step S105 (step S105: No), the process returns to the processing of the step S101.

When it is evaluated that the predetermined time has not passed from after the volume change operation in the step S106 (step S106: No), the notification processing unit 414 evaluates as to whether or not there is a notification item information (step S107). That is, in a state where the evaluation as to whether or not there is a notification item information is sequentially executed, the notification processing unit 414 detects generation of the notification item information within the predetermined time from after the predetermined volume change operation. When it is evaluated that the predetermined time has passed from after the volume change operation in the step S106 (step S106: Yes), the process returns to the processing of the step S101.

When it is determined that there is a notification item information in the step S107 (step S107: Yes), the notification processing unit 414 starts the notification processing (step S108). At this time, the display processing unit 412 distinctly shows the display of the notification display part 226 so that the display can be easily spotted by the user. When it is evaluated that there is no notification item information in the step S107 (step S107: No), the process returns to the processing of the step S106.

After the processing of the step S104 or the processing of the step S108, the sound processing unit 413 evaluates as to whether or not the predetermined time has passed from after the volume change operation in the step S103 or the step S105 (step S109). The predetermined time which is evaluated in this step is the same as the predetermined time which is evaluated in step 106. When it is evaluated that the predetermined time has passed from after the volume change in the step S109 (step S109: Yes), the display processing unit 412 returns the notification display that has been changed in the notification processing started in the step S104 or S108 to normal display (step S110). When it is evaluated that the predetermined time has not passed from after the volume change in the step S109 (step S109: No), the process returns to the processing of the step S109.

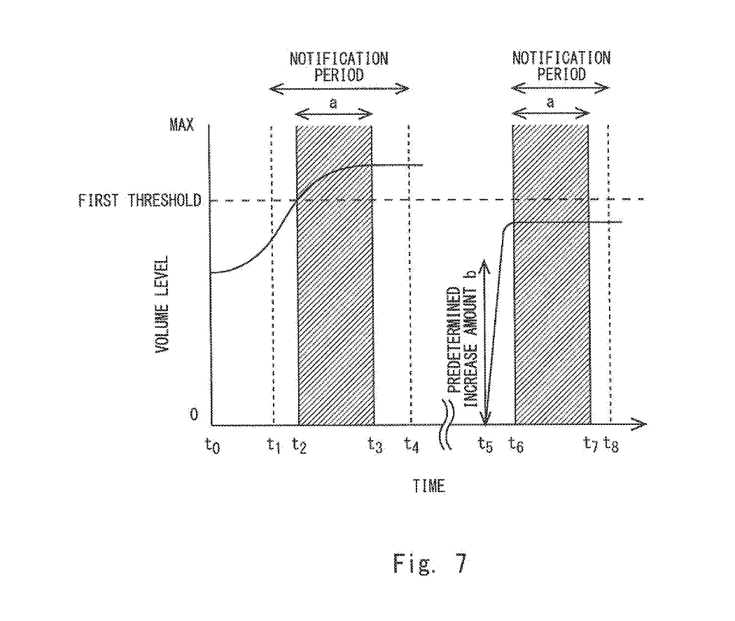

A specific example of volume change timings and notification display timings in the above flow of processing will be described by referring to FIG. 7. Although the example described by referring to FIG. 7 is an example when the volume is increased, this example is also applicable to the case when the volume is reduced.

The vertical axis in FIG. 7 represents a volume level that can be arbitrarily changed from level zero to level MAX by the user operating the operation input unit 405. The horizontal axis represents a time axis.

When the user operates the operation input unit 405 and performs the operation to increase the volume from the time t₀, and while the volume is increasing as indicated by the solid line, the notification processing unit 414 determines that there is a notification item information (step S101: Yes) and starts the notification display from the time t₁ (step S102). When the volume exceeds the first threshold at the time t₂ while the notification display is continued (step S103: Yes), the display processing unit 412 changes the notification display to make it distinct so that the display can be easily spotted by the user in a period a from the time t₂ to the time t₃ (steps S104, S109, and S110).

The display processing unit 412 returns the display of the notification display part 226 to the normal display at the time t₃ (step S110). Even when the volume level at this time is greater than or equal to the first threshold, it is possible to achieve the object of attracting the user's attention to the notification display part 226 when the user is distracted from the notification due to the change in the volume.

In this example, although the notification display is ended at the time t₄ which is later than the time at which the notification display is returned (step S111: Yes), if the notification display is ended before the period a ends, the notification display is ended at a timing when the notification display is ended even when the notification display is changed.

As another example, when the user operates the operation input unit 405 and increases the volume by an amount greater than or equal to a predetermined volume increase from the time t₅ (step S105: Yes), if it is within the predetermined time from after the volume change (step S106: No), and if it is evaluated that there is a notification item information at the time t₆ (step S107: Yes), the notification processing unit 414 starts the notification processing, and the display processing unit 412 changes the notification display to make it distinct so that the display can be easily spotted by the user during a period a from the time t₆ to t₇ (steps S108, S109, and S110).

The predetermined amount of volume increase in this case is a predetermined volume increase obtained within a predetermined time and is, for example, a volume increase of 50% or greater in one second, which is a unit of time, when a volume increase from volume zero to volume MAX is considered to be 100%.

When such a volume increase greater than or equal to the predetermined volume increase is obtained, even when increased volume is less than the first threshold as shown in FIG. 7, the notification display is changed. Alternatively, in addition to a volume increase greater than or equal to the predetermined increase, a case when an increased volume exceeds the first threshold may be added to the condition for changing the notification display.

In a display method by the display device 100 according to the first exemplary embodiment and a display program executed by the display device 100 according to the first exemplary embodiment, the steps S103 and S105 correspond to a volume information obtaining step. The steps S101 and S107 correspond to a notification information obtaining step. The steps from S104 to S110 and from S108 to S110 correspond to a display changing step.

By performing such processing, the display device 100 changes the display mode according to the volume change information so that the notification display is easily spotted by the user. This enables the user to notice the notification display even when the attention of the user is focused on the sound output, the volume of which has been changed. Therefore, according to this embodiment, it is possible to appropriately display a notification to a user.

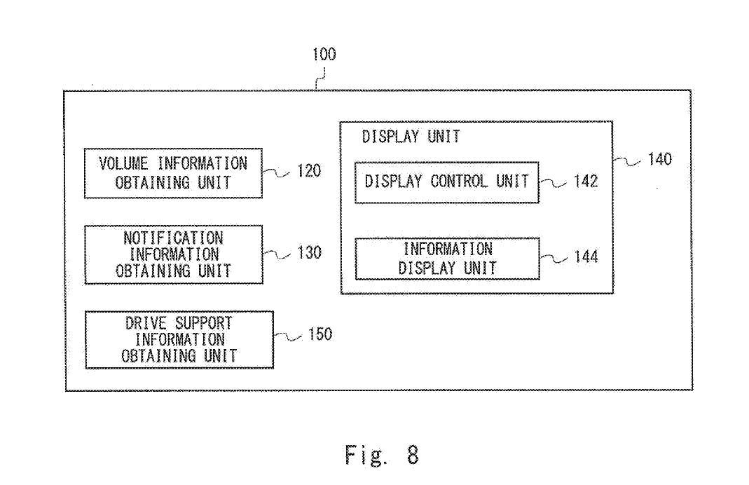

Next, a second exemplary embodiment of the display device 100 will be described by referring to FIGS. 8 to 10. The parts of the description of the display device 100 according to the second exemplary embodiment that are common to the description of the display device 100 according to the first exemplary embodiment will be omitted.

In a manner similar to the display device 100 according to the first exemplary embodiment, the display device 100 according to the second exemplary embodiment is configured using the HUD device 200 that projects and display various information items inside an automobile as virtual images and the media playback device 400. A difference from the display device 100 according to the first exemplary embodiment is that, as shown in FIG. 8, the display device 100 according to the second exemplary embodiment includes a drive support information obtaining unit 150.

When the automobile including the display device 100 is equipped with a drive support function, the drive support information obtaining unit 150 obtains information indicating as to whether or not drive support is executed. The drive support here indicates both limited support for drive operations of the user and full support for drive operations of the user. An example of the partial drive support is an autocruise function etc., and an example of the full drive support is autonomous driving, etc.

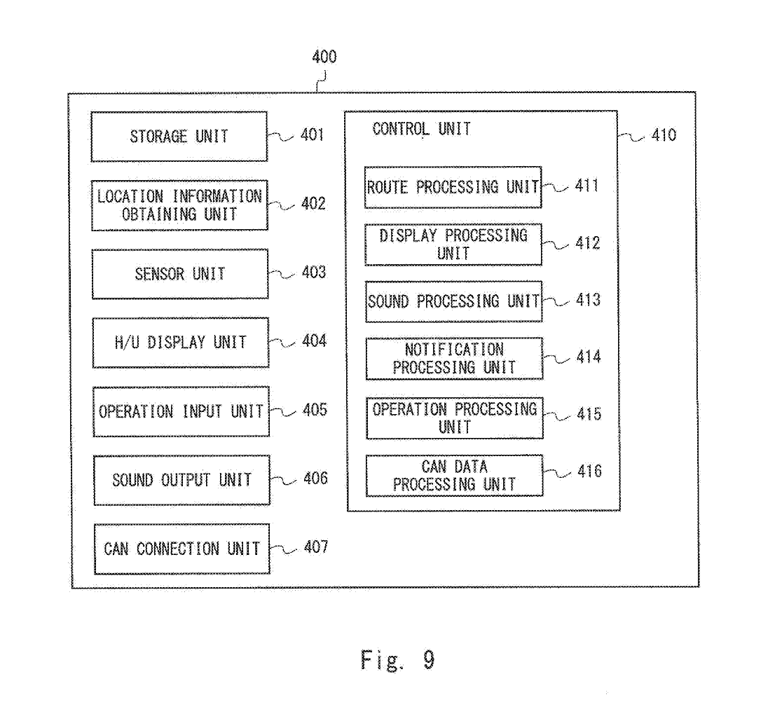

The drive support information obtaining unit 150 obtains information related to such drive support from, for example, a CAN (Controller Area Network), which is an on-board network. Thus, in the configuration of the media playback device 400, as shown in FIG. 9, the drive support information obtaining unit 150 corresponds to a CAN connection unit 407 and a CAN data processing unit 416 that is a function of the control unit 410.

The CAN connection unit 407 is an interface for connections to the CAN. The CAN data processing unit 416 obtains CAN information according to a purpose via the CAN connection unit 407 and performs processing on the CAN information to use it. Further, the CAN data processing unit 416 evaluates as to whether or not the drive support is executed according to obtained CAN data.

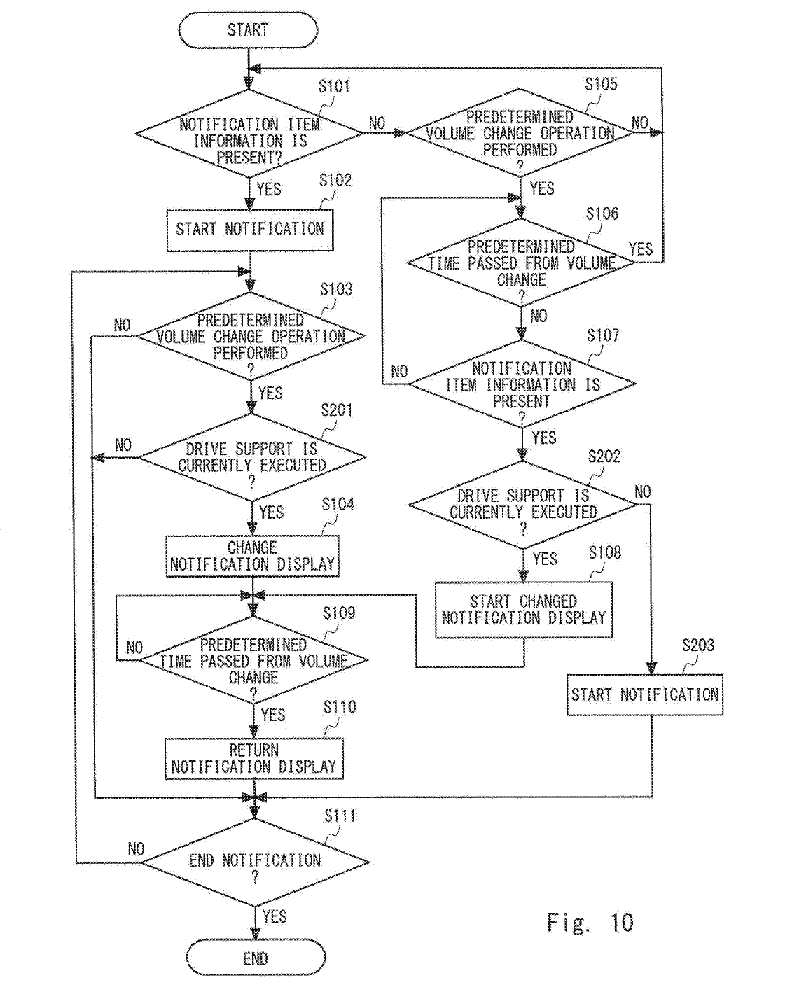

In an operation example shown in FIG. 10, when it is evaluated that the predetermined volume change operation has been accepted in the step S103 (step S103: Yes), the CAN data processing unit 416 evaluates as to whether or not the drive support is executed (step S201). When it is evaluated that the drive support is executed in the step S201 (step S201: Yes), the display processing unit 412 changes the display of the notification display part 226 displayed in the notification processing of the step S102 to make it distinct so that the display can be easily spotted by the user (step S104). When it is evaluated that the drive support is not executed (step S201: No), the processing of the step S111 is executed.

Likewise, when it is evaluated that there is a notification item information in the step S107 (step S107: Yes), the CAN data processing unit 416 evaluates as to whether or not the drive support is executed (step S202). When it is evaluated that the drive support is executed in the step S202 (step S202: Yes), the notification processing unit 414 starts the notification processing (step S108). At this time, the display processing unit 412 distinctly shows the display of the notification display part 226 so that the display can be easily spotted by the user. When it is evaluated that the drive support is not executed in the step S202 (step S202: No), the notification processing unit 414 starts the notification processing (step S203). At this time, the display processing unit 412 shows the display of the notification display part 226 in a normal display mode.

By performing such processing, the display device 100 changes the display mode so that the notification display can be easily spotted by the user according to the volume change information while the drive support is executed. This enables the user to notice the notification display even when the attention of the user is focused on the sound output due to the change in the volume during the drive support when the user tends to be more focused on the sound output of the contents than during normal drive.

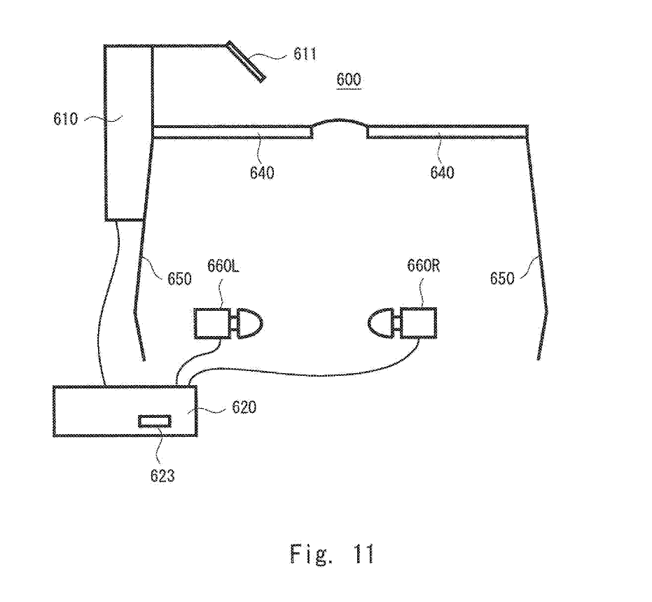

Although the display device 100 has been described as a device used inside an automobile, the exemplary embodiment is effective not only for the display device used inside an automobile. Next, a third exemplary embodiment of the display device 100 will be described by referring to FIGS. 11 to 14. The parts of the description of the display device 100 according to the third exemplary embodiment that are common to the description of the display device 100 according to the first exemplary embodiment will be omitted.

FIG. 11 is a drawing schematically showing an HMD device 600 and a media playback device 620 that constitute the display device 100. The HMD device 600 is a spectacle or goggle device that is worn on a head of the user, and the media playback device 620 may be in any form such as a portable device or a device integrated with the HMD device 600 as long as it can output various information items to the HMD device 600.

The HMD device 600 is configured to include an HMD projection unit 610, a half mirror 611, spectacle lens units 640, spectacle temple units 650, and the like. The media playback device 620 includes an operation input unit 624, and earphones 660 (a left earphone 660L and a right earphone 660R) that output sound signals to the user are connected to the media playback device 620. The earphones 660 may be any headphones or small speakers that are connected to the media playback device 620. Alternatively, the earphones 660 may be integrated with the HMD device 600.

When sound signals are included in contents to be played, the media playback device 620 outputs the sound signals to the earphones 660, and when video signals are further included in the contents to be played, the media playback device 620 also outputs the video signals to the HMD projection unit 610.

The HMD projection unit 610 projects video light based on the input video signals on the half mirror 611 so that the user wearing the HMD device 600 can see the video reflected by the half mirror 611 through the spectacle lens units 640.

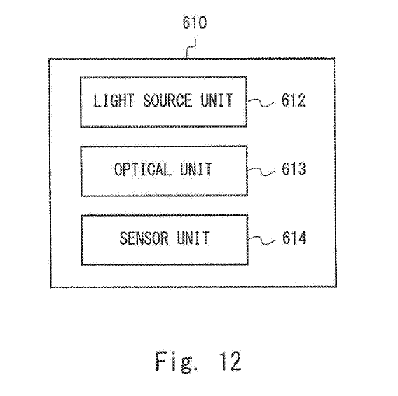

FIG. 12 is a configuration block diagram of the HMD projection unit 610. The HMD projection unit 610 includes a light source unit 612, an optical unit 613, and a sensor unit 614.

The light source unit 612 generates the video light to be presented to the user. As a specific example of the light source unit 612, the light source unit 612 includes a liquid crystal panel that constructs video to be presented, an LED element that is a light source for projecting constructed video on the liquid crystal panel, and the like. The optical unit 613 is an optical part that generates a light path for guiding the video light generated by the light source unit 612 to the half mirror 611 and includes a lens that enlarges or reduces the video light, a reflecting mirror, and the like.

The sensor unit 614 includes one or a plurality of sensors. To be more specific, the sensor unit 614 includes a GPS reception unit that obtains current location information, an acceleration sensor and an orientation sensor that detect an orientation of the HMD device 600 and a moving direction. The sensor unit 614 may be a camera that images a forward direction and the like of the user who is wearing the HMD device 600.

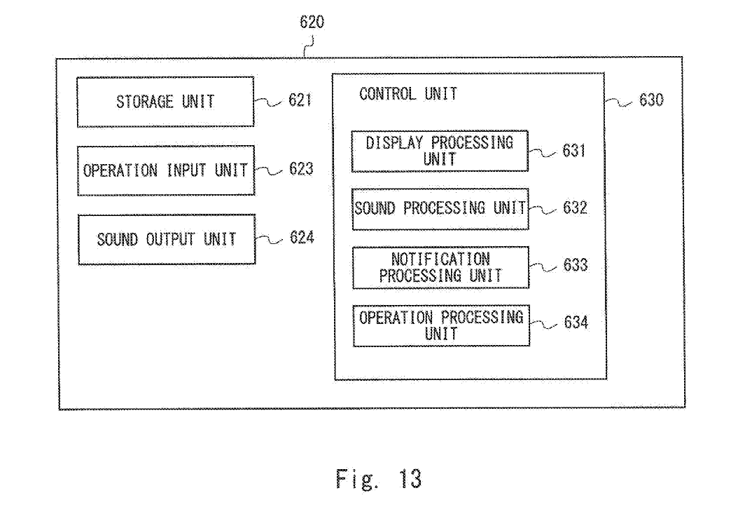

As mentioned above, the media playback device is portable or integrated with the HMD device 600, and as shown in FIG. 13, is configured to include a storage unit 621, an operation input unit 623, a sound output unit 624, and a control unit 630.

The storage unit 621 has the same configuration as that of the storage unit 401 and stores sound contents and video contents. The operation input unit 623 has the same configuration as that of the operation input unit 405 and accepts adjustment operations of the playback volume of the contents played by the media playback device 620.

The sound output unit 624 has the same configuration as that of the sound output unit 406 and outputs sound of various contents played by the media playback device 620. The sound output unit 624 outputs the sound signals, on which processing such as decoding is performed by the sound processing unit 632, which will be described later, to the earphones 660 shown in FIG. 11.

The control unit 630 has the same configuration as that of the control unit 410 and achieves a display processing unit 631, a sound processing unit 632, a notification processing unit 633, and an operation processing unit 634 as functions operated by programs stored in a RAM and the like. The display processing unit 631 has the same function as that of the display processing unit 412 and controls display of information output to the HMD projection unit 610. The sound processing unit 632 has the same function as that of the sound processing unit 413.

The notification processing unit 633 has the same function as that of the notification processing unit 414. To be more specific, for example, the notification processing unit 633 issues a notification display instruction to the display processing unit 631 when there is a notification item in an area around the user based on the current location information obtained from the GPS reception unit which is the sensor unit 614. Further, by analyzing images captured by a camera, which is the sensor unit 614, the notification processing unit 633 detects the presence of the notification item and issues a notification display instruction to the display processing unit 631. Examples of the notification item are: stairs and a construction site in the travelling direction, a vehicle coming close to the user, and the like.

The operation processing unit 634 has the same function as that of the operation processing unit 415 and performs processing to accept operations on the operation input unit 624. More specifically, for example, when an operation of changing the playback volume is performed on the operation input unit 624 while the media playback device 620 plays the sound contents or the video contents including sound, the sound processing unit 632 changes the playback volume in response to the operation based on an evaluation by the operation processing unit 634 that volume operation processing is performed and based on an amount of the operation.

In the display device 100 according to the third exemplary embodiment, the operation input unit 623 and the operation processing unit 634 function as the volume information obtaining unit 120. The sensor unit 614 and the notification processing unit 633 function as the notification information obtaining unit 130. The display processing unit 631 corresponds to the display control unit 142 that constitutes the display unit 140, and the HMD device 600 corresponds to the information display unit 144.

An operation example of the display device 100 according to the third exemplary embodiment is the same as that of the display device 100 according to the first exemplary embodiment shown in FIG. 5.

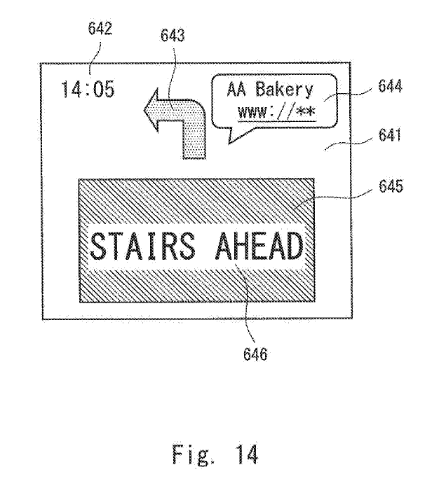

FIG. 14 shows an example of a notification executed in the step S102, and is an example in which the notification is displayed on a virtual image 641 that is projected by the HMD device 600. As an example, a time display part 642, a destination display part 643, a facility information display part 644, and a contents display part 645 are displayed on the virtual image 641. In the steps S102 and S108, the notification display part 646 is displayed.

The time display part 642 displays a current time and the like. When destination is previously set and destination guide processing is operating, the destination display part 643 displays an arrow indicating the destination on a road or an intersection in an actual landscape that is visually recognized through the spectacle lens units 640 according to the map information stored in the storage unit 621. When the destination has not been set or the destination display part 643 is not equipped with a function for setting a destination, the destination display part 643 displays arrows indicating options and the like of travelling directions on a road or an intersection in an actual landscape that is visually recognized through the spectacle lens units 640 according to the map information.

The facility information display part 644 displays information related to a facility in the actual landscape that is visually recognized through the spectacle lens units 640. To be more specific, the information is a name of a store, a URL of the store, reviews of the store, and the like. The contents display part 645 displays a playback screen of the contents played by the media playback device 620. The contents display part 645 may be a Web screen based on the URL or the like of the facility information display part 644.

The notification display part 646 is displayed by an instruction from the notification processing unit 633. In the example of FIG. 14, the notification display part 646 indicates that there are stairs, which are a notification item, in the travelling direction according to the current location information of the HMD device 600, the moving direction of the user who is wearing the HMD device 600, and the map information stored in the storage unit 621.

While the notification display part 646 is being displayed, and when the notification display is changed in response to the volume change as in the step S104 or S108, the display processing unit 631 changes the display of the notification display part 646 to make it distinct so that the display can be easily spotted by the user.

A display position of the notification display part 646 may be, as shown in FIG. 14, at a position overlapping the contents display part 645. In addition, the notification display part 646 may be displayed at a position not overlapping the contents display part 645 in a normal notification, and when the notification display is changed in response to the volume change, the notification display part 646 may be displayed at a position overlapping the contents display part 645.

By performing such processing, the display device 100 changes the display mode according to the volume change information so that the notification display is easily spotted by the user. This enables the user to notice the notification display even when the attention of the user is focused on the sound output due to a change in the volume while the user is wearing the HMD device 600.

Although the present invention has been described with reference to the exemplary embodiments, the present invention is not limited by the same. Various modifications, obvious to those skilled in the art, can be made to the configurations and details of the present invention within the scope of the invention.

What is claimed is:

1. A display device comprising:
a volume information obtaining unit configured to obtain volume change information for a sound output;
a notification information obtaining unit configured to obtain notification information for a user; and
a display unit configured to provide the user with a notification display according to the notification information obtained by the notification information obtaining unit and change a display mode so that the notification display will be easily spotted by the user for a period that attracts a user's attention to sound due to a change in volume of the sound when the volume change information obtained by the volume information obtaining unit indicates a volume change to predetermined volume or higher, a volume change to the predetermined volume or lower, a volume change by a volume increase of a predetermined amount or greater, or a volume change by a volume reduction of a predetermined amount or greater.

2. The display device according to claims 1, wherein
the display device is used inside a vehicle, and
the notification information obtaining unit obtains the notification information according to information outside the vehicle for the user.

3. The display device according to claim 2, further comprising a drive support information obtaining unit configured to obtain information indicating as to whether or not the vehicle is in a drive support state, wherein the display unit changes the display mode so that the notification display will be distinct according to the volume change information obtained by the volume information obtaining unit when the drive support information obtained by the drive support information obtaining unit indicates that the vehicle is in the drive support state.

4. The display device according to claims 1, wherein
the display device is worn by the user, and
the notification information obtaining unit obtains the notification information according to a state of surroundings around the user.

5. A display method executed by a display device comprising:
a volume information obtaining step for obtaining volume change information for a sound output;
a notification information obtaining step for obtaining notification information for a user; and
a display changing step for providing the user with a notification display according to the notification information obtained in the notification information obtaining step and changing a display mode so that the notification display will be easily spotted by the user for a period that attracts a user's attention to sound due to a change in volume of the sound when the volume change information obtained in the volume information obtaining step indicates a volume change to predetermined volume or higher, a volume change to the predetermined volume or lower, a volume change by a volume increase of a predetermined amount or greater, or a volume change by a volume reduction of a predetermined amount or greater.

6. A non-transitory computer readable medium storing a display program that causes a computer for controlling a display device to display information in a range of user's view to execute:
a volume information obtaining step for obtaining volume change information for a sound output;
a notification information obtaining step for obtaining notification information for a user; and
a display changing step for providing the user with a notification display according to the notification information obtained in the notification information obtaining step and changing a display mode so that the notification display will be easily spotted by the user for a period that attracts a user's attention to sound due to a change in volume of the sound when the volume change information obtained in the volume information obtaining step indicates a volume change to predetermined volume or higher, a volume change to the predetermined volume or lower, a volume change by a volume increase of a predetermined amount or greater, or a volume change by a volume reduction of a predetermined amount or greater.
